(19) United States
(12) Patent Application Publication
(10) Pub. No.: US 2025/0372555 A1
(43) Pub. Date: Dec. 4, 2025

(54) ELECTRONIC MODULE AND MANUFACTURING METHOD OF ELECTRONIC MODULE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Yoshitaka KATO, Nisshin-shi (JP); Takeshi ENDO, Nisshin-shi (JP)

(21) Appl. No.: 19/203,329

(22) Filed: May 9, 2025

(30) Foreign Application Priority Data
May 28, 2024 (JP) 2024-086408

(51) Int. Cl. H01L 23/00; H01L 25/16; H10D 80/20; H10D 80/30

(52) U.S. Cl. CPC H01L 24/10; H01L 24/05; H01L 24/13; H01L 24/16; H01L 25/16; H10D 80/251; H10D 80/30; H01L 2224/05022; H01L 2224/05073; H01L 2224/10125; H01L 2224/13014; H01L 2224/13016; H01L 2224/13023; H01L 2224/13026; H01L 2224/16057; H01L 2224/16145; H01L 2924/3511

(57) ABSTRACT

In an electronic module, electrode pads of a first circuit component and electrode pads of a second circuit component are arranged such that conductive bonding members disposed between the electrode pads of the first circuit component and the electrode pads of the second circuit component form bonding member groups, each of which includes two or more conductive bonding members arranged along one direction in a plane direction of the first circuit component, with the one direction being defined as an extension direction of each of the bonding member groups. Each of reinforcing members is disposed apart from an adjacent bonding member group among the bonding member groups, and each of the reinforcing members has a first portion that extends along a direction intersecting with the extension direction of the adjacent bonding member group, and a second portion that extends along the extension direction of the adjacent bonding member group.

### CROSS REFERENCE TO RELATED APPLICATION

The present application claims the benefit of priority from Japanese Patent Application No. 2024-086408 filed on May 28, 2024. The entire disclosure of the above application is incorporated herein by reference.

### TECHNICAL FIELD

The present disclosure relates to an electronic module and a manufacturing method of an electronic module.

### BACKGROUND

Conventionally, electronic modules in which a first circuit component and a second circuit component are laminated and electrically connected to each other have been proposed.

### SUMMARY

An electronic module according to an aspect of the present disclosure includes a first circuit component, a second circuit component, a plurality of conductive bonding members, a plurality of reinforcing members, and an insulating bonding material. Electrode pads of the first circuit component and electrode pads of the second circuit component are arranged such that the conductive bonding members disposed between the electrode pads of the first circuit component and the electrode pads of the second circuit component form bonding member groups, each of which includes two or more conductive bonding members arranged along a first direction in a plane direction of the first circuit component, with the first direction being defined as an extension direction of each of the bonding member groups. Each of the reinforcing members is disposed apart from an adjacent bonding member group among the bonding member groups, and each of the reinforcing members has a first portion that extends along a direction intersecting with the extension direction of the adjacent bonding member group, and a second portion that extends along the extension direction of the adjacent bonding member group.

A manufacturing method according to another aspect of the present disclosure is a manufacturing method of the electronic module according to the above aspect, and includes arranging the electrode pads of the first circuit component and the electrode pads of the second circuit component such that three or more of the bonding member groups are to be arranged in a second direction of the plane direction of the first circuit component, and applying the insulating bonding material from each position located between two of the bonding member groups that are adjacent to each other in the second direction.

### BRIEF DESCRIPTION OF DRAWINGS

Objects, features and advantages of the present disclosure will become apparent from the following detailed description made with reference to the accompanying drawings. In the drawings:

FIG. 1 is a perspective view of an electronic module according to a first embodiment;

FIG. 2 is a cross-sectional view of the electronic module taken along line II-II of FIG. 1;

FIG. 3 is a cross-sectional view of the electronic module taken along line III-III of FIG. 2;

FIG. 4A is a cross-sectional view illustrating a manufacturing process of the electronic module illustrated in FIG. 1;

FIG. 4B is a cross-sectional view illustrating a manufacturing process of the electronic module subsequent to FIG. 4A;

FIG. 4C is a cross-sectional view illustrating a manufacturing process of the electronic module subsequent to FIG. 4B;

FIG. 5 is a diagram showing the relationship between a protrusion amount of a reinforcing member from a bonding member group and a stress generated in a conductive bonding member;

FIG. 6 is a diagram showing the relationship between a width of the reinforcing member and a stress generated in the conductive bonding member;

FIG. 7 is a diagram for explaining the protrusion amount of the reinforcing member from the bonding member group, the width of the reinforcing member, and a distance between the reinforcing member and the bonding member group;

FIG. 8 is a cross-sectional view illustrating an electronic module according to a second embodiment;

FIG. 9A is a cross-sectional view illustrating a state in which an insulating bonding material flows in the vicinity of a reinforcing member in which a first portion and a second portion are connected;

FIG. 9B is a cross-sectional view illustrating a state in which the insulating bonding material flows, subsequent to FIG. 9A;

FIG. 10A is a cross-sectional view illustrating a state in which an insulating bonding material flows in the vicinity of a reinforcing member in which a first portion and a second portion are apart from each other;

FIG. 10B is a cross-sectional view illustrating a state in which the insulating bonding material flows, subsequent to FIG. 10A;

FIG. 11A is a cross-sectional view illustrating a state in which an insulating bonding material flows in the vicinity of a reinforcing member that has a gap at which a first portion and a second portion are apart from each other and that has two second portions sandwiching a bonding member group therebetween;

FIG. 11B is a cross-sectional view illustrating a state in which the insulating bonding material flows, subsequent to FIG. 11A;

FIG. 12 is a cross-sectional view illustrating a state in which an insulating bonding material flows when the insulating bonding material is applied from one position;

FIG. 13A is a cross-sectional view illustrating a state in which an insulating bonding material flows when the insulating bonding material is applied from two positions;

FIG. 13B is a cross-sectional view illustrating a state in which the insulating bonding material flows, subsequent to FIG. 13A;

FIG. 13C is a cross-sectional view illustrating a state in which the insulating bonding material flows, subsequent to FIG. 13B;

FIG. 14 is a diagram illustrating the relationship between the shape of the reinforcing member and the stress generated in the conductive bonding member;

FIG. 15A is a cross-sectional view illustrating a reinforcing member of shape A in FIG. 14;

FIG. 15B is a cross-sectional view illustrating a reinforcing member of shape B in FIG. 14;

FIG. 15C is a cross-sectional view illustrating a reinforcing member of shape C in FIG. 14;

FIG. 15D is a cross-sectional view illustrating a reinforcing member of shape D in FIG. 14;

FIG. 16 is a cross-sectional view illustrating an electronic module according to a third embodiment;

FIG. 17 is a diagram illustrating the relationship between the shape of the reinforcing member and the stress generated in the conductive bonding member;

FIG. 18A is a cross-sectional view illustrating a shape of a reinforcing member according to another embodiment;

FIG. 18B is a cross-sectional view illustrating a shape of a reinforcing member according to another embodiment; and

FIG. 18C is a cross-sectional view illustrating a shape of a reinforcing member according to another embodiment.

### DETAILED DESCRIPTION

Next, a relevant technology is described only for understanding the following embodiments. An electronic module includes a first circuit component and a second circuit component that are laminated. In the electronic module, first electrode pads are arranged on a surface of the first circuit component facing the second circuit component, and second electrode pads are arranged on a surface of the second circuit component facing the first circuit component. The first circuit component and the second circuit component are electrically connected via conductive bonding members disposed between the first electrode pad and the second electrode pad. The first electrode pads and the second electrode pads are arranged so as to overlap in the laminating direction of the first circuit component and the second circuit component, and are arranged side by side along one direction on the surface of the first circuit component.

Between the first circuit component and the second circuit component, reinforcing members are disposed in the vicinity of the first electrode pads and the second electrode pads. The reinforcing members extend along the arrangement direction of the first electrode pads and the second electrode pads and are connected to the first circuit component and the second circuit component. Furthermore, an insulating bonding material such as an underfill is disposed between the first circuit component and the second circuit component.

The above-described electronic module can be manufactured as follows. The second circuit component is laminated above the first circuit component such that the conductive bonding members are disposed between the first electrode pads and the second electrode pads, and the reinforcing members are disposed in the vicinity of the first electrode pads and the second electrode pads. Next, a first heating process is performed to fix the conductive bonding members to the first electrode pads and the second electrode pads, and to fix the reinforcing members to the first circuit component and the second circuit component. Then, after the temperature is lowered to room temperature, the insulating bonding material is applied between the first circuit component and the second circuit component, and a second heating process is performed to fix the insulating bonding material to the first circuit component and the second circuit component to manufacture the electronic module.

In the above-described electronic module, the reinforcing members are formed to extend in the one direction on the surface of the first circuit component. Therefore, in the above-described electronic module, when the conductive bonding members are fixed to the first electrode pads and the second electrode pads by heating and then the temperature is lowered, if stress that causes warpage in a direction along an axis in the one direction on the surface of the first circuit component, there is a possibility that the stress generated in the conductive bonding members are not reduced by the reinforcing members.

An electronic module according to a first aspect of the present disclosure includes a first circuit component, a second circuit component, a plurality of conductive bonding members, a plurality of reinforcing members, and an insulating bonding material. The first circuit component has a surface on which a plurality of electrode pads are disposed. The second circuit component is laminated above the first circuit component, and has a surface facing the surface of the first circuit component and on which a plurality of electrode pads are disposed. The plurality of conductive bonding members are disposed between the plurality of electrode pads of the first circuit component and the plurality of electrode pads of the second circuit component, respectively, and electrically connect the plurality of electrode pads of the first circuit component and the plurality of electrode pads of the second circuit component, respectively. The plurality of reinforcing members are disposed between the surface of the first circuit component and the surface of the second circuit component and are bonded to the surface of the first circuit component and the surface of the second circuit component. The insulating bonding material is disposed between the surface of the first circuit component and the surface of the second circuit component, bonded to the surface of the first circuit component and the surface of the second circuit component, and made of a material different from the plurality of conductive bonding members and the plurality of reinforcing members. The plurality of electrode pads of the first circuit component and the plurality of electrode pads of the second circuit component are arranged such that the plurality of conductive bonding members disposed between the plurality of electrode pads of the first circuit component and the plurality of electrode pads of the second circuit component form a plurality of bonding member groups, each of which includes two or more of the plurality of conductive bonding members arranged along one direction in a plane direction of the surface of the first circuit component, with the one direction being defined as an extension direction of each of the plurality of bonding member groups. Each of the plurality of reinforcing members is disposed apart from an adjacent bonding member group among the plurality of bonding member groups, and each of the plurality of reinforcing members has a first portion that extends along a direction intersecting with the extension direction of the adjacent bonding member group, and a second portion that extends along the extension direction of the adjacent bonding member group.

According to this configuration, since each of the plurality of reinforcing members has the first portion and the second portion extending in different directions, when the temperature is lowered after the plurality of conductive bonding members are fixed to the first circuit component and the second circuit component, the stress generated in the plurality of conductive bonding members can be reduced. Therefore, damage to the plurality of conductive bonding members can be suppressed.

A manufacturing method according to a second aspect of the present disclosure is a manufacturing method of an electronic module that includes a first circuit component, a second circuit component, a plurality of conductive bonding members, a plurality of reinforcing members, and an insulating bonding material. The first circuit component has a surface on which a plurality of electrode pads are disposed. The second circuit component is laminated above the first circuit component, and has a surface facing the surface of the first circuit component and on which a plurality of electrode pads are disposed. The plurality of conductive bonding members are disposed between the plurality of electrode pads of the first circuit component and the plurality of electrode pads of the second circuit component, respectively, and electrically connect the plurality of electrode pads of the first circuit component and the plurality of electrode pads of the second circuit component, respectively. The plurality of reinforcing members are disposed between the surface of the first circuit component and the surface of the second circuit component and are bonded to the surface of the first circuit component and the surface of the second circuit component. The insulating bonding material is disposed between the surface of the first circuit component and the surface of the second circuit component, bonded to the surface of the first circuit component and the surface of the second circuit component, and made of a material different from the plurality of conductive bonding members and the plurality of reinforcing members. The plurality of electrode pads of the first circuit component and the plurality of electrode pads of the second circuit component are arranged such that the plurality of conductive bonding members disposed between the plurality of electrode pads of the first circuit component and the plurality of electrode pads of the second circuit component form a plurality of bonding member groups, each of which includes two or more of the plurality of conductive bonding members arranged along a first direction in a plane direction of the surface of the first circuit component, with the first direction being defined as an extension direction of each of the plurality of bonding member groups. Each of the plurality of reinforcing members is disposed apart from an adjacent bonding member group among the plurality of bonding member groups, and each of the plurality of reinforcing members has a first portion that extends along a direction intersecting with the extension direction of the adjacent bonding member group, and a second portion that extends along the extension direction of the adjacent bonding member group. The manufacturing method includes preparing the first circuit component and the second circuit component, disposing the plurality of conductive bonding members and the plurality of reinforcing members between the first circuit component and the second circuit component, and disposing the insulating bonding material between the first circuit component and the second circuit component by flowing the insulating bonding material. The preparing of the first circuit component and the second circuit component includes arranging the plurality of electrode pads of the first circuit component and the plurality of electrode pads of the second circuit component such that three or more of the plurality of bonding member groups are to be arranged in a second direction of the plane direction of the first circuit component. The disposing of the insulating bonding material includes applying the insulating bonding material from each position located between two of the plurality of bonding member groups that are adjacent to each other in the second direction.

According to this manufacturing method, it is possible to prevent the insulating bonding material from wrapping around and merging in the vicinity of the plurality of bonding member groups, thereby preventing the occurrence of voids within the insulating bonding material due to the merging.

Embodiments of the present disclosure will be described below with reference to the drawings. In the following embodiments, the same or equivalent parts are denoted by the same reference numerals for description.

### First Embodiment

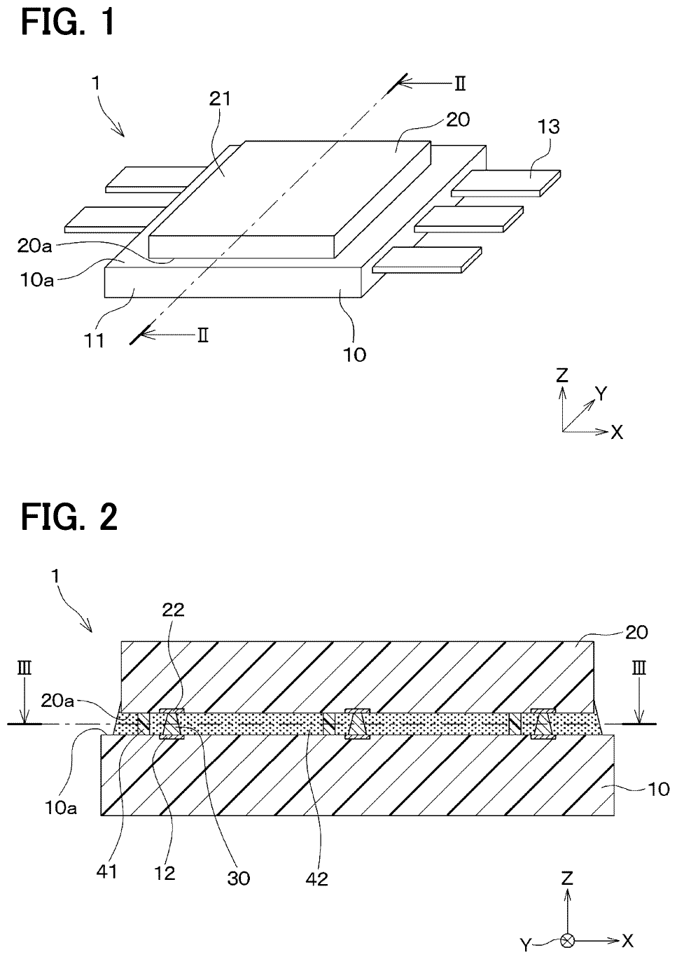

An electronic module 1 according to a first embodiment will be described with reference to the drawings. The electronic module 1 of the present embodiment is preferably mounted on a vehicle such as an automobile and used to drive various electronic devices for the vehicle. As shown in FIG. 1 and FIG. 2, the electronic module 1 of the present embodiment includes a power module 10 and a circuit module 20. In the present embodiment, the power module 10 corresponds to a first circuit component, and the circuit module 20 corresponds to a second circuit component.

Although not shown in the drawings, the power module 10 includes a semiconductor chip on which a gate-type switching element, which is a power semiconductor, is formed, and the semiconductor chip is sealed with a mold resin 11. The switching element is, for example, a metal oxide semiconductor field effect transistor (MOSFET), and has a gate terminal, a source terminal, and a drain terminal. However, the switching element may be an insulated gate bipolar transistor (IGBT) or the like. The power module 10 also includes terminal portions 13 that are connected to a source terminal and a drain terminal of the semiconductor chip. The power module 10 of the present embodiment has a generally rectangular shape with long and short sides in plan view.

Although not shown in the drawings, the circuit module 20 has a wiring board and on which a gate control circuit is formed. The gate control circuit is connected to the gate terminal of the switching element disposed within the power module 10, and controls the gate voltage to the gate terminal. The wiring board is sealed with a mold resin 21. The circuit module 20 of the present embodiment has a generally rectangular shape with long and short sides in plan view, and is smaller in plan view than the power module 10.

The electronic module 1 is configured by laminating the circuit module 20 above the power module 10, and electrically connecting the semiconductor chip of the power module 10 to the wiring board of the circuit module 20. In FIG. 2, the power module 10 and the circuit module 20 are illustrated in a simplified manner, and in reality, the semiconductor chip is disposed within the power module 10, and the wiring board is disposed within the circuit module 20.

In the following description, a surface of the power module 10 facing the circuit module 20 is referred to as a surface 10a of the power module 10, and a surface of the circuit module 20 facing the power module 10 is referred to as a surface 20a of the circuit module 20. In the following description, the laminating direction of the power module 10 and the circuit module 20 is defined as a Z-axis direction, a direction perpendicular to the Z-axis direction is defined as an X-axis direction, and a direction perpendicular to the X-axis direction and the Z-axis direction is defined as a Y-axis direction. The X-axis direction and the Y-axis direction are also directions along plane directions of the surface 10a of the power module 10 and the surface 20a of the circuit module 20. In addition, in the present embodiment, the X-axis direction is a direction parallel to the long sides of the power module 10 and the circuit module 20, and the Y-axis direction is a direction parallel to the short sides of the power module 10 and the circuit module 20 (that is, perpendicular to the long sides). That is, in the present embodiment, the power module 10 and the circuit module 20 are laminated so that their long sides are parallel to the X-axis direction and their short sides are parallel to the Y-axis direction. In the present embodiment, the power module 10 and the circuit module 20 are laminated such that the circuit module 20 is located within the power module 10 when viewed along the Z-axis direction.

As shown in FIG. 2, the power module 10 has a plurality of electrode pads 12 on the surface 10a. Although details are omitted, the electrode pads 12 are electrically connected to the semiconductor chip disposed in the power module 10. Similarly, the circuit module 20 has a plurality of electrode pads 22 on the surface 20a. Although details are omitted, the electrode pads 22 are electrically connected to the wiring board disposed within the circuit module 20.

The number of the electrode pads 12 of the power module 10 is the same as the number of the electrode pads 22 of the circuit module 20. The electrode pads 12 and the electrode pads 22 are arranged to overlap in the Z-axis direction when the power module 10 and the circuit module 20 are laminated. The circuit module 20 is laminated above the power module 10 such that the surface 20a faces the surface 10a, and the electrode pads 22 face the electrode pads 12, respectively. Note that, the term “in the Z-axis direction” can be rephrased as “when viewed from the Z-axis direction”.

Conductive bonding members 30 are disposed between the electrode pads 12 of the power module 10 and the electrode pads 22 of the circuit module 20, and the conductive bonding members 30 are fixed to the electrode pad 12 and the electrode pads 22. As a result, the electrode pads 12 of the power module 10 and the electrode pads 22 of the circuit module 20 are electrically connected via the conductive bonding members 30. The conductive bonding members 30 are made of, for example, a conductive adhesive made of a mixture of a conductive material and a resin. However, the conductive bonding members 30 may be made of solder or the like.

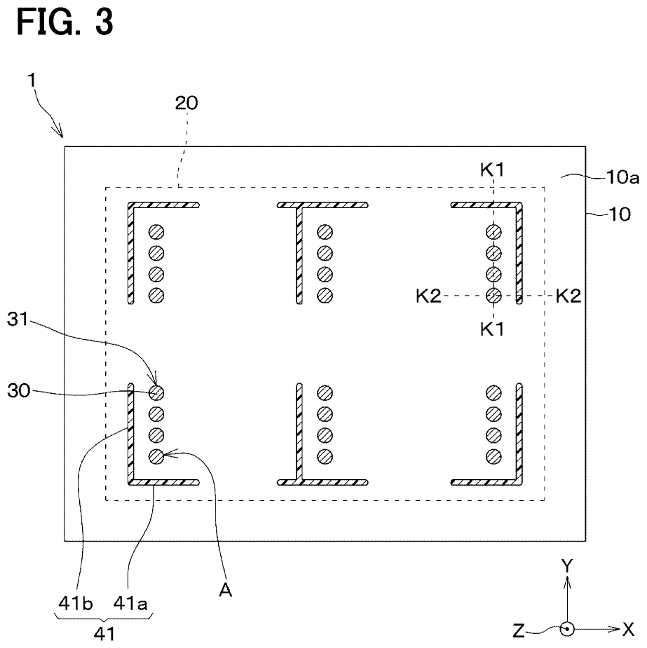

As shown in FIG. 3, the electrode pads 12, 22 of the present embodiment are arranged such that the conductive bonding members 30 disposed between the electrode pads 12 and the electrode pads 22 form a plurality of bonding member groups 31 each of which includes two or more of the conductive bonding members 30 arranged along the Y-axis direction. In the present embodiment, the electrode pads 12, 22 are arranged such that four conductive bonding members 30 are arranged in the Y-axis direction to form one bonding member group 31. In other words, the electrode pads 12, 22 are arranged so as to form electrode pad groups in each of which has four electrode pads 12, 22 arranged in the Y-axis direction. In the present embodiment, the electrode pads 12, 22 are arranged such that six bonding member groups 31 are formed. More specifically, in the present embodiment, the electrode pads 12, 22 are arranged such that three bonding member groups 31 are arranged in the X-axis direction, and two sets of the three bonding member groups 31 are arranged in the Y-axis direction. In FIG. 3, an insulating bonding material 42, which will be described later, is omitted, and an outline of the circuit module 20 is indicated by a dotted line. In the present embodiment, the Y-axis direction corresponds to a first direction in the plane direction of the surface 10a of the power module 10, and an extension direction of each of the bonding member groups 31.

As shown in FIG. 2, reinforcing members 41 and the insulating bonding material 42 are disposed between the power module 10 and the circuit module 20. The reinforcing members 41 are made of an adhesive such as epoxy or the same material as the conductive bonding members 30. The insulating bonding material 42 is made of an underfill or the like. In the present embodiment, the reinforcing members 41 and the insulating bonding material 42 are made of materials with higher coefficients of linear expansion than the conductive bonding members 30.

As shown in FIG. 3, the reinforcing members 41 are disposed adjacent to the bonding member groups 31, respectively, and are fixed to the surface 10a of the power module 10 and the surface 20a of the circuit module 20. In the present embodiment, the six bonding member groups 31 are arranged, and therefore six reinforcing members 41 are arranged and fixed to the surface 10a of the power module 10 and the surface 20a of the circuit module 20. Each of the reinforcing members 41 is disposed apart from the adjacent bonding member group 31 and the adjacent electrode pads 12, 22 and is not in contact with the adjacent bonding member group 31 and the adjacent electrode pads 12, 22.

Each of the reinforcing members 41 is configured to have a first portion 41a and a second portion 41b. The first portion 41a extends in the X-axis direction so as to intersect with a virtual line K1 extending along the Y-axis direction passing through the adjacent bonding member group 31. The second portion 41b extends in the Y-axis direction so as to intersect with a virtual line K2 extending along the X-axis direction passing through the adjacent bonding member group 31. In other words, each of the reinforcing members 41 is configured to have the second portion 41b extending along an extension direction of the adjacent bonding member group 31, and the first portion 41a extending from one end side of the second portion 41b along a direction intersecting the extension direction of the second portion 41b. In other words, each of the reinforcing members 41 has the first portion 41a and the second portion 41b extending in two different directions (that is, perpendicular directions). Each of the reinforcing members 41 of the present embodiment has a generally L-shape in plan view, with the first portion 41a and the second portion 41b connected to each other. As will be described later, the reinforcing members 41 serve to reduce stress generated in the conductive bonding members 30 (that is, the bonding member groups 31). Therefore, each of the reinforcing members 41 is disposed apart from the adjacent conductive bonding members 30 (that is, the adjacent bonding member group 31), but is disposed at a position capable of reducing the stress generated in the adjacent conductive bonding members 30.

As shown in FIG. 2, the insulating bonding material 42 is disposed so as to cover the conductive bonding members 30 and the reinforcing members 41, and is fixed to the surface 10a of the power module 10 and the surface 20a of the circuit module 20.

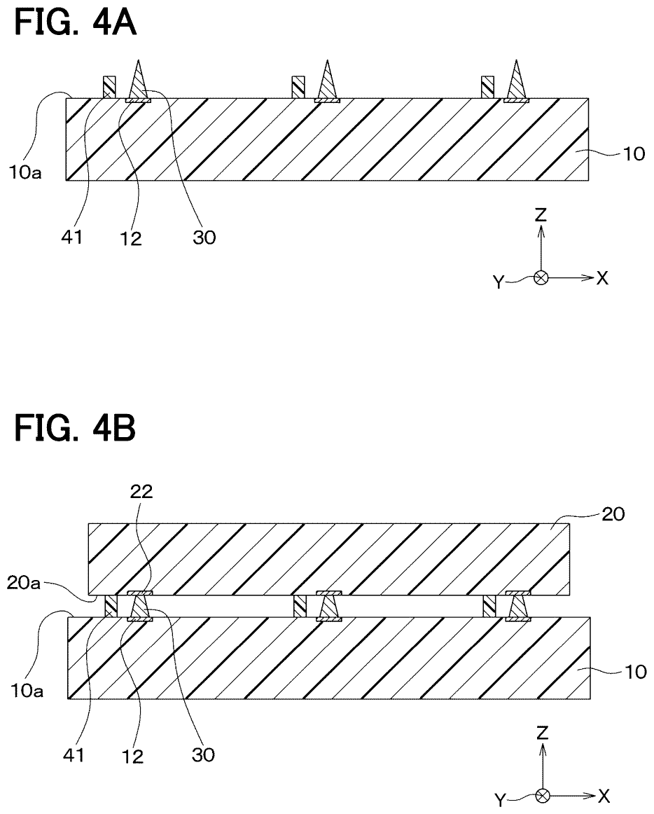

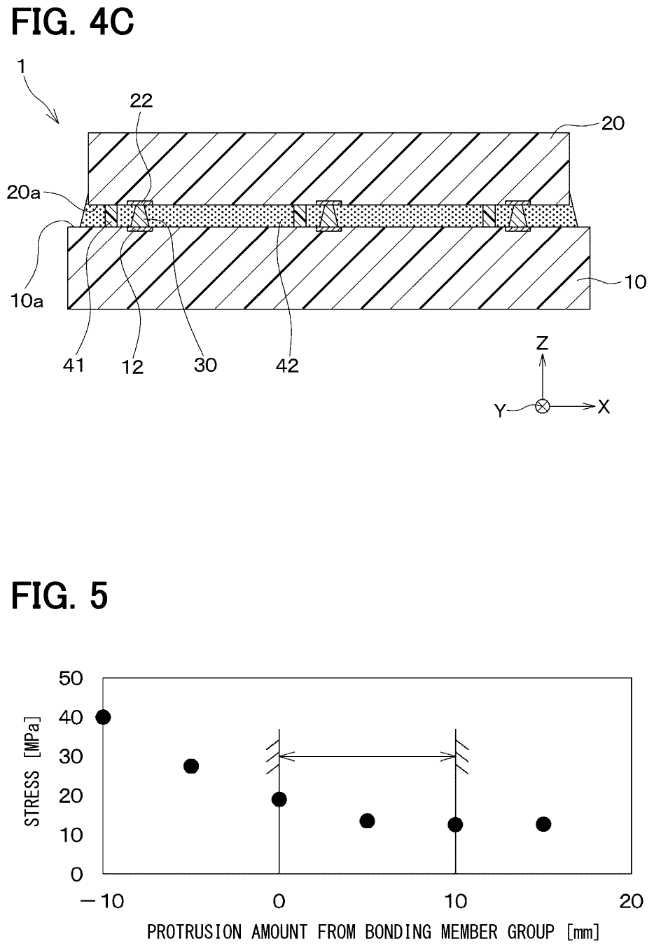

The above is the configuration of the electronic module 1 in the present embodiment. Next, a manufacturing method of the electronic module 1 of the present embodiment will be described with reference to FIGS. 4A to 4C, and a more detailed configuration will be described. FIGS. 4A to 4C are cross-sectional views of a portion corresponding to FIG. 2.

First, as shown in FIG. 4A, the power module 10 having the electrode pads 12 on the surface 10a is prepared. Then, on the surface 20a side of the power module 10, the conductive bonding members 30 are applied onto the electrode pads 12, and the reinforcing members 41 are applied around the conductive bonding members 30 (that is, the electrode pads 12) using a dispenser or the like. The conductive bonding members 30 may be a conductive paste that constitutes a conductive adhesive (that is, a paste in which a conductive material, a resin, and a solvent are mixed (for example, silver paste)) or may be cream solder. The conductive bonding members 30 may also be preformed solder (for example, solder balls and the like). When the conductive bonding members 30 are preformed solder, instead of applying the conductive bonding members 30, the conductive bonding members 30 are placed on the electrode pads 12. The reinforcing members 41 are applied so as not to come into contact with the electrode pads 12 and the conductive bonding members 30. When the conductive bonding members 30 and the reinforcing members 41 are made of the same material, the conductive bonding members 30 and the reinforcing members 41 are applied in the same process. Although an example in which the conductive bonding members 30 and the reinforcing members 41 are applied to the power module 10 is described here, the conductive bonding members 30 and the reinforcing members 41 may be applied to the circuit module 20.

Next, as shown in FIG. 4B, the circuit module 20 having the electrode pads 22 on the surface 20a is prepared. Then, the circuit module 20 is laminated above the power module 10 such that the electrode pads 12 of the power module 10 and the electrode pads 22 of the circuit module 20 face each other. As a result, the conductive bonding members 30 and the reinforcing members 41 are positioned between the power module 10 and the circuit module 20, with the conductive bonding members 30 in contact with both of the electrode pads 12, 22 and the reinforcing members 41 in contact with both of the surfaces 10a, 20a. The conductive bonding members 30 and the reinforcing members 41 spread laterally due to pressure being applied when the circuit module 20 is placed above the power module 10. Therefore, the electrode pads 12, 22 and the reinforcing members 41 are arranged so as to be out of contact with each other even if the conductive bonding members 30 and the reinforcing members 41 spread laterally.

Thereafter, a first heating process is performed in which a laminate of the power module 10 and the circuit module 20 is heated. As a result, the conductive bonding members 30 are fixed to the electrode pads 12 and 22, and the reinforcing members 41 are fixed to the surface 10a of the power module 10 and the surface 20a of the circuit module 20. Specifically, in a case where the conductive bonding members 30 are conductive paste, the conductive bonding members 30 are hardened by heating and are fixed to the electrode pads 12 and 22. In a case where the conductive bonding members 30 are solder, the conductive bonding members 30 melt when heated, and then solidify and adhere to the electrode pads 12 and 22 when the temperature of the laminate is lowered.

When the conductive bonding members 30 are heated, outgassing is generated from the conductive bonding members 30. That is, in the case where the conductive bonding members 30 are conductive paste, the solvent contained in the conductive paste volatilizes due to heating, generating outgassing. In the case where the conductive bonding members 30 are solder, a flux contained in the solder volatilizes due to heating, generating outgassing. In these cases, in the present embodiment, the conductive bonding members 30 and the reinforcing members 41 are positioned apart from each other and outer peripheral surfaces of the conductive bonding members 30 are exposed, so that outgassing generated in the conductive bonding members 30 is discharged to the outside of the laminate. This prevents the formation of voids inside the reinforcing members 41 due to the outgassing from the conductive bonding members 30. Furthermore, the reinforcing members 41 are hardened by heating and are fixed to the surface 10a of the power module 10 and the surface 20a of the circuit module 20.

Next, after the conductive bonding members 30 and the reinforcing members 41 are fixed to their respective objects, the temperature of the laminate is lowered to room temperature. At this time, in the process of lowering the temperature of the laminate, the power module 10 and the circuit module 20 each shrink. Since there is a difference in the coefficient of linear expansion between the circuit module 20 and the power module 10, the circuit module 20 and the power module 10 have different amounts of shrinkage. As a result, a shear stress is applied to the conductive bonding members 30 disposed between the power module 10 and the circuit module 20. Furthermore, because the amount of contraction differs between the circuit module 20 and the power module 10, warping occurs in the power module 10 and the circuit module 20. As a result, a tensile stress is applied to the conductive bonding members 30 disposed between the power module 10 and the circuit module 20.

At this time, in the present embodiment, not only the conductive bonding members 30 but also the reinforcing members 41 are disposed between the power module 10 and the circuit module 20. Each of the reinforcing members 41 has the first portion 41a extending in the X-axis direction and the second portion 41b extending in the Y-axis direction. Therefore, in the present embodiment, the shrinkage of the power module 10 and the circuit module 20 is suppressed, and warping of the power module 10 and the circuit module 20 around the X-axis direction and around the Y-axis direction can be suppressed. Therefore, the thermal stress applied to the conductive bonding members 30 due to the temperature drop is reduced. Accordingly, the damage to the conductive bonding members 30 due to the temperature drop can be suppressed.

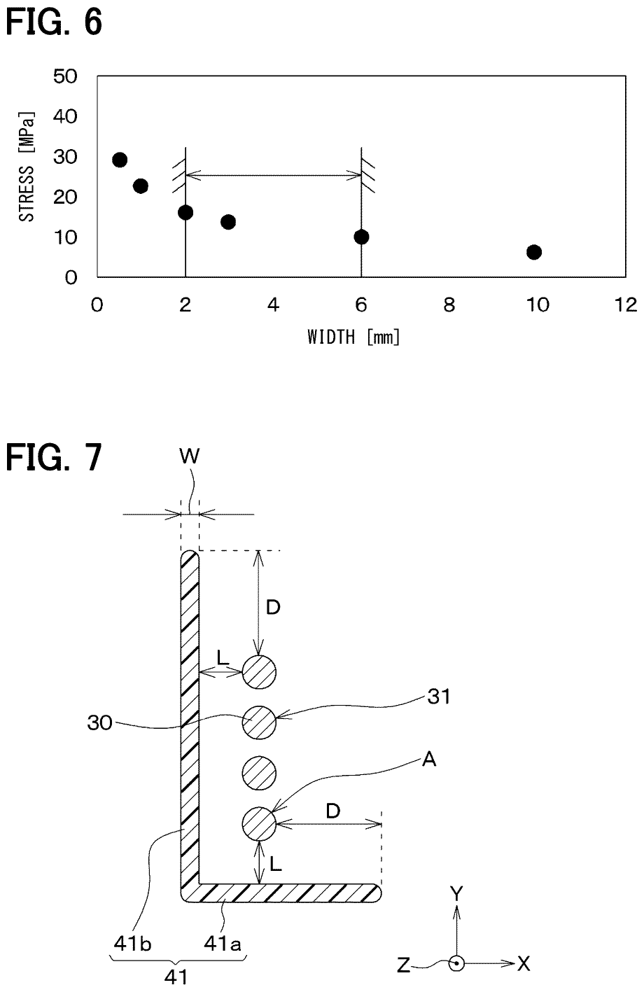

The present inventors conducted extensive research into the relationship between the configuration of the reinforcing member 41 and the stress generated in the conductive bonding member 30, and obtained the results shown in FIG. 5 and FIG. 6. FIG. 5 shows the results of investigating the stress generated in the conductive bonding member 30 indicated by the arrow A in FIG. 3 and FIG. 7 when the temperature of the laminate was lowered to room temperature after the first heating process. Hereinafter, as shown in FIG. 7, in the reinforcing member 41, the amount of protrusion of an end of the first portion 41a opposite the second portion 41b from the bonding member group 31 in the X-axis direction is defined as a protrusion amount D. Similarly, the amount of protrusion of an end of the second portion 41b opposite the first portion 41a from the bonding member group 31 in the Y-axis direction is referred to as a protrusion amount D. A width of the reinforcing member 41 is defined as W. The width W of the reinforcing member 41 refers to a length along the Y-axis direction at the first portion 41a, and refers to a length along the X-axis direction at the second portion 41b. In the present embodiment, the width W of the reinforcing member 41 is uniform in both the X-axis direction and the Y-axis direction. Furthermore, a distance between the reinforcing member 41 and the bonding member group 31 is defined as L.

As shown in FIG. 5, it was confirmed that the stress generated in the conductive bonding member 30 decreases sharply as the protrusion amount D approaches 0 in a range where the protrusion amount D is less than 0 mm. It was also confirmed that the stress generated in the conductive bonding member 30 gradually decreases as the protrusion amount D increases in the range of the protrusion amount D longer than 0 mm and equal to or less than 10 mm. It was also confirmed that the stress generated in the conductive bonding member 30 hardly changes when the protrusion amount D is in a range longer than 10 mm. However, the longer the protrusion length D, the more likely it is that the process of applying the reinforcing member 41 will become longer, and the manufacturing process will be extended. For this reason, it is preferable that the protrusion amount D is greater than 0 mm and equal to or less than 10 mm. In addition, in FIG. 5, the protrusion amount D of less than 0 mm means that the end of the first portion 41a opposite the second portion 41b and the end of the second portion 41b opposite the first portion 41a do not protrude from the bonding member group 31.

Furthermore, as shown in FIG. 6, it was confirmed that the stress generated in the conductive bonding member 30 decreases sharply as the width W approaches 2 mm in a range where the width W is less than 2 mm. It was also confirmed that the stress generated in the conductive bonding member 30 gradually decreases as the width W increases within the range of 2 mm or more and 6 mm or less. It was also confirmed that the stress generated in the conductive bonding member 30 hardly changes when the width W is in the range of 6 mm or more. However, the wider the width W, the more likely it is that the process of applying the reinforcing members 41 will become longer, and the manufacturing process will be extended. For this reason, in the present embodiment, it is preferable that the width W is set to be 2 mm or more and 6 mm or less.

In the present embodiment, the distance L between each of the reinforcing members 41 and the adjacent bonding member group 31 is set to about 0.5 to 3.0 mm so that the conductive bonding members 30 and the reinforcing members 41 do not come into contact with each other even if they spread laterally due to pressure when the circuit module 20 is placed above the power module 10.

Next, as shown in FIG. 4C, the insulating bonding material 42 is applied and filled into a gap between the surface 10a of the power module 10 and the surface 20a of the circuit module 20 (that is, around the conductive bonding members 30 and the reinforcing members 41). The insulating bonding material 42 is filled so as to cover the outer peripheral surfaces of the conductive bonding members 30 and the outer peripheral surfaces of the reinforcing members 41 and to come into contact with the surface 10a of the power module 10 and the surface 20a of the circuit module 20.

Subsequently, a second heating process is performed in which the laminate of the power module 10 and the circuit module 20 is heated again. As a result, the insulating bonding material 42 is hardened and fixed to the surface 10a of the power module 10 and the surface 20a of the circuit module 20. The insulating bonding material 42 adheres closely to the outer peripheral surfaces of the conductive bonding members 30 to protect the conductive bonding members 30.

According to the present embodiment described above, each of the reinforcing members 41 has the first portion 41a and the second portion 41b extending in different directions. Therefore, when the temperature is lowered after the conductive bonding members 30 are fixed to the power module 10 and the circuit module 20, the stress generated in the conductive bonding members 30 can be reduced. Therefore, damage to the conductive bonding members 30 can be suppressed.

In the present embodiment, the first portion 41a and the second portion 41b are formed to be connected to each other. Therefore, when applying the material for the first portion 41a and the second portion 41b that constitute each of the reinforcing members 41, the material can be applied continuously, which simplifies the manufacturing process.

In the present embodiment, it is preferable that the protrusion amount D from the bonding member group 31 of the end of the first portion 41a located opposite the second portion 41b, and the protrusion amount D from the bonding member group 31 of the end of the second portion 41b located opposite the first portion 41a are greater than 0 mm and less than or equal to 10 mm. This makes it possible to sufficiently reduce the stress generated in the conductive bonding members 30 when the temperature is lowered after the conductive bonding members 30 are fixed to the power module 10 and the circuit module 20.

In the present embodiment, it is preferable that the width W of each of the reinforcing members 41 is set to be 2 mm or more and 6 mm or less. This makes it possible to sufficiently reduce the stress generated in the conductive bonding members 30 when the temperature is lowered after the conductive bonding members 30 are fixed to the power module 10 and the circuit module 20.

In the present embodiment, the reinforcing members 41 and the insulating bonding material 42 have higher coefficients of linear expansion than the conductive bonding members 30. Here, according to the investigation by the present inventors, it was confirmed that after manufacturing the electronic module 1, if the coefficient of linear expansion of the insulating bonding material 42 is less than that of the conductive bonding members 30, the stress generated in the conductive bonding members 30 is likely to increase. Similarly, it was confirmed that if the coefficient of linear expansion of the reinforcing members 41 is less than that of the conductive bonding members 30, the stress generated in the conductive bonding members 30 is likely to increase. Therefore, in the present embodiment, the coefficients of linear expansion of the reinforcing members 41 and the insulating bonding material 42 are set to be higher than the coefficient of linear expansion of the conductive bonding members 30, making it easier to reduce the stress generated in the conductive bonding members 30.

In the present embodiment, since the reinforcing members 41 are disposed as described above, the conductive bonding members 30 can be made of a conductive adhesive with low bonding strength. Therefore, in the present embodiment, the selectability of the material for the conductive bonding members 30 can be improved.

In the present embodiment, when the reinforcing members 41 are made of the same material as the conductive bonding members 30, the reinforcing members 41 and the conductive bonding members 30 can be applied in the same process, thereby simplifying the manufacturing process.

In the present embodiment, the reinforcing members 41 are not in contact with the conductive bonding members 30. Therefore, when the first heating process is performed, it is possible to suppress the formation of voids in the reinforcing members 41 due to the outgassing from the conductive bonding members 30. Furthermore, since the insulating bonding material 42 is formed after the first heating process, the insulating bonding material 42 is not affected by the outgassing from the conductive bonding members 30. Therefore, the formation of voids in the insulating bonding material 42 can be suppressed.

### Second Embodiment

The following describes a second embodiment of the present disclosure. The present embodiment is different from the first embodiment in the configuration of the reinforcing members 41. The other configurations of the present embodiment are similar to those of the first embodiment, and therefore a description of the similar configurations will not be repeated.

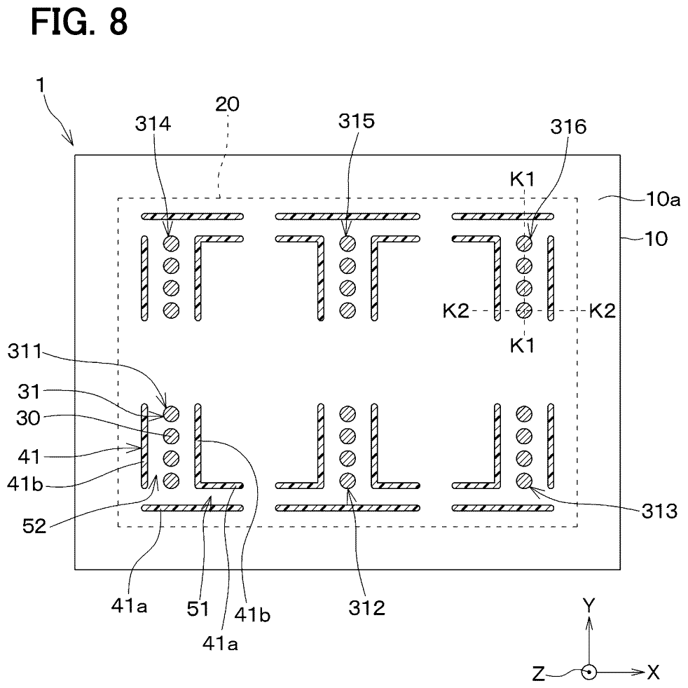

As shown in FIG. 8, in the electronic module 1 of the present embodiment, three bonding member groups 31 are arranged in the X-axis direction, as in the first embodiment described above, and two sets of the three bonding member groups 31 are arranged in the Y-axis direction. Hereinafter, in the present embodiment, the three bonding member groups 31 arranged along the X-axis direction are also referred to as first to third bonding member groups 311 to 313 and fourth to sixth bonding member groups 314 to 316. FIG. 8 is a cross-sectional view corresponding to FIG. 3. In FIG. 8, the first to third bonding member groups 311 to 313 are arranged along the X-axis direction from the lower left side of the page, and fourth to sixth bonding member groups 314 to 316 are arranged along the X-axis direction from the upper left side of the page. In the present embodiment, the X-axis direction corresponds to a second direction in the plane direction of the surface 10a of the power module 10.

Each of the reinforcing members 41 arranged adjacent to the first, third, fourth, and sixth bonding member groups 311, 313, 314, and 316, which are located at both ends in the X-axis direction, has two second portions 41b arranged on either side of each of the bonding member groups 31. Furthermore, each of the reinforcing members 41 has two first portions 41a that are disposed at ends of the second portion 41b along the Y-axis direction on the long side of the surface 10a of the power module 10. In each of the reinforcing members 41 of the present embodiment, a first passage 51 is defined between the two first portions 41a, and a second passage 52 is defined between the two second portions 41b. In addition, each of the bonding member groups 31 is disposed so as to be located within the second passage 52.

The first portions 41a of the reinforcing members 41 arranged in the vicinity of the first and third bonding member groups 311 and 313 extend toward the second bonding member group 312. The first portions 41a of the reinforcing members 41 arranged in the vicinity of the fourth and sixth bonding member groups 314, 316 are arranged so as to extend toward the fifth bonding member group 315. Of the two first portions 41a, one located close to the long side of the surface 10a of the power module 10 is disposed apart from the second portion 41b. In other words, each of the reinforcing members 41 is configured to have a gap at which the first portion 41a and the second portion 41b are apart from each other.

Each of the reinforcing members 41 arranged adjacent to the second and fifth bonding member groups 312, 315, which are located on the central side in the X-axis direction, has two second portions 41b arranged on either side of the bonding member group 31. In addition, each of the reinforcing members 41 has the first portion 41a extending on the opposite side to the bonding member group 31 from the end of each of the second portions 41b along the Y-axis direction close to the long side of the surface 10a of the power module 10. Furthermore, each of the reinforcing members 41 further has the first portion 41a extending in the X-axis direction so as to intersect with a virtual line K1 that extends along the Y-axis direction passing through each of the bonding member groups 31, and is arranged to form a first passage 51 between the first portions 41a connected to the second portion 41b.

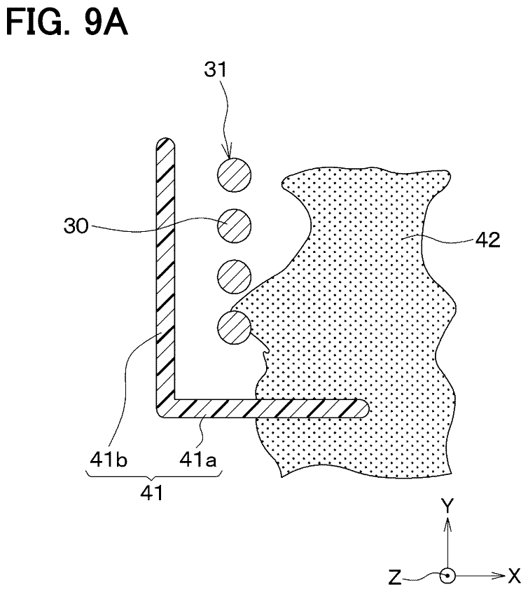

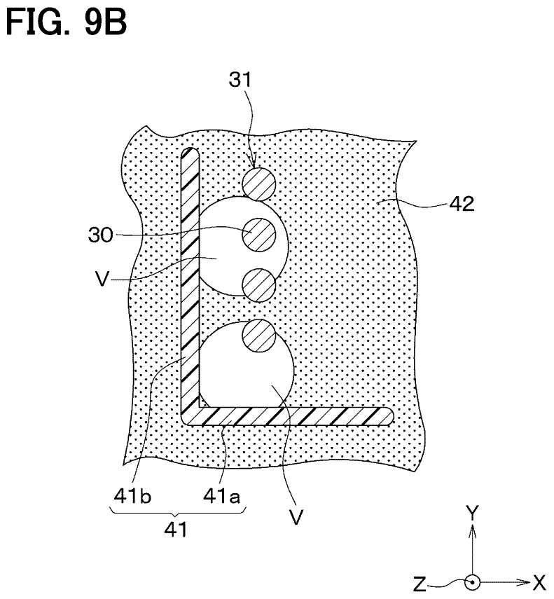

The above is the configuration of the electronic module 1 in the present embodiment. Here, in the above-described first embodiment, when the insulating bonding material 42 is applied, the insulating bonding material 42 is applied from a predetermined position between the surface 10a of the power module 10 and the surface 20a of the circuit module 20, and then spreads overall while flowing in the space between the surface 10a of the power module 10 and the surface 20a of the circuit module 20. At this time, due to factors such as partial differences in surface roughness of each of the surfaces 10a and 20a, differences in the spreading speed of the insulating bonding material 42 may occur. Therefore, for example, when the insulating bonding material 42 spreads as shown in FIG. 9A, there is a possibility that voids V due to entrapment of air may occur in the vicinity of the bonding member group 31 as shown in FIG. 9B.

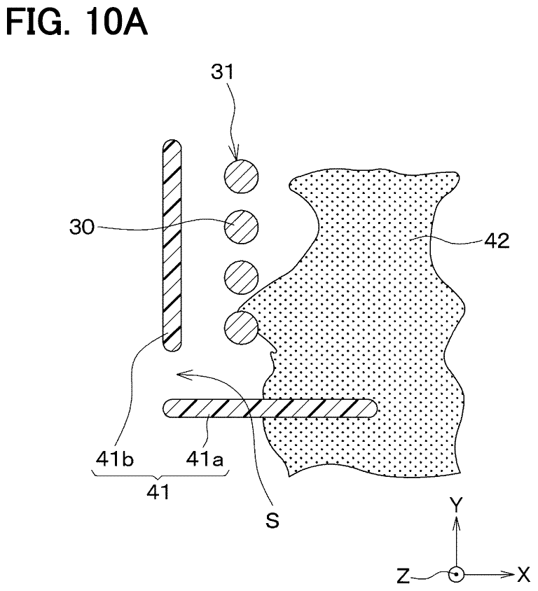

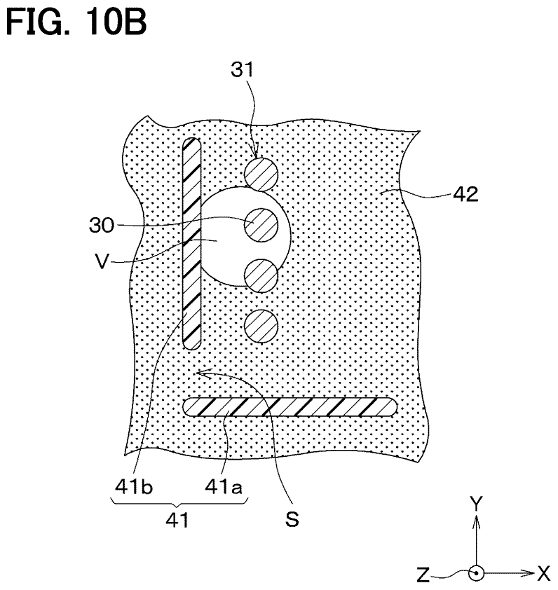

For this reason, in the present embodiment, each of the reinforcing members 41 has the gap at which the first portion 41a and the second portion 41b are apart from each other. As a result, when the insulating bonding material 42 flows as shown in FIG. 10A, the insulating bonding material 42 is discharged through a gap S between the first portion 41a and the second portion 41b as shown in FIG. 10B, thereby preventing the occurrence of voids V in a portion between the first portion 41a and the second portion 41b.

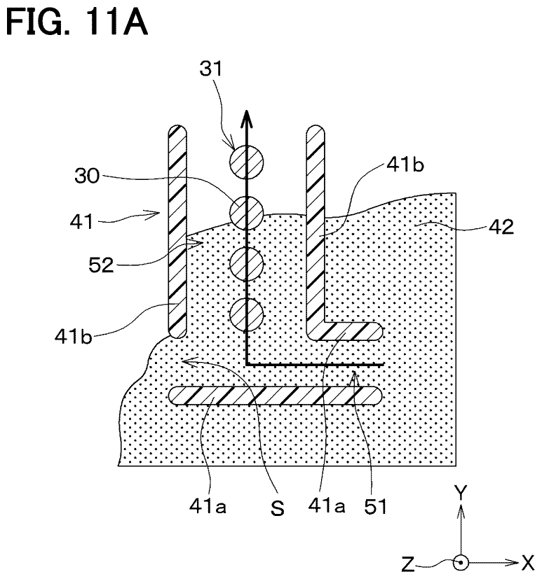

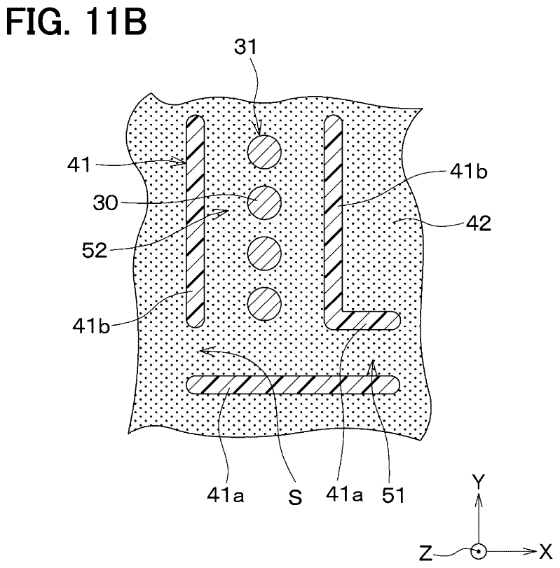

In the present embodiment, the two second portions 41b are disposed on either side of the bonding member group 31 so that a flow direction of the insulating bonding material 42 relative to the bonding member group 31 is in the one direction. More specifically, the bonding member group 31 is arranged within the second passage 52. This allows the insulating bonding material 42 to easily flow in the one direction through the second passage 52 as shown in FIG. 11A, and prevents the occurrence of voids V in the vicinity of the bonding member group 31 as shown in FIG. 11B. In the present embodiment, the first passage 51 connected to the second passage 52 is configured by the two first portions 41a so that the insulating bonding material 42 can easily flow in the one direction through the second passage 52.

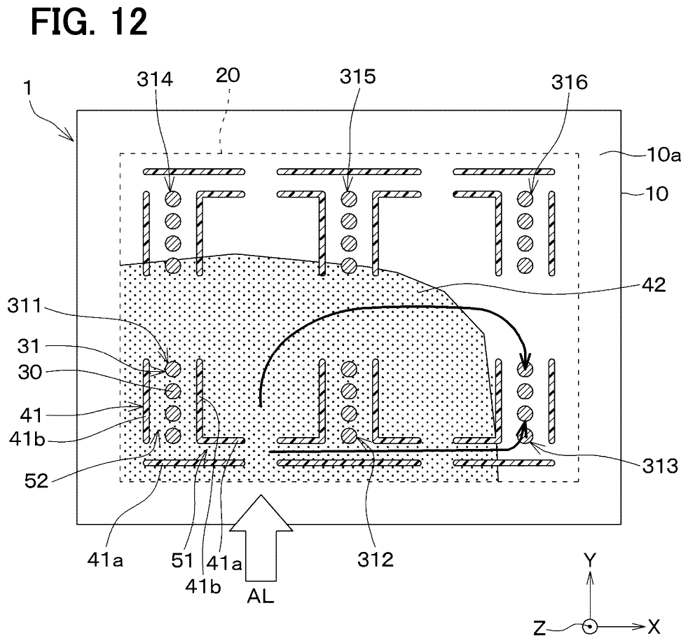

Furthermore, in a case where the plurality of bonding member groups 31 are provided as in the present embodiment, when attempting to fill the insulating bonding material 42 from one application position, the insulating bonding material 42 may flow around and cause the insulating bonding material 42 to merge around the bonding member groups 31, which may result in voids V at the merged portion. For example, as shown in FIG. 12, when the insulating bonding material 42 is applied from an application position AL between the first bonding member group 311 and the second bonding member group 312, the insulating bonding material 42 may merge in the vicinity of the third bonding member group 313, and a void V may occur at the merged portion.

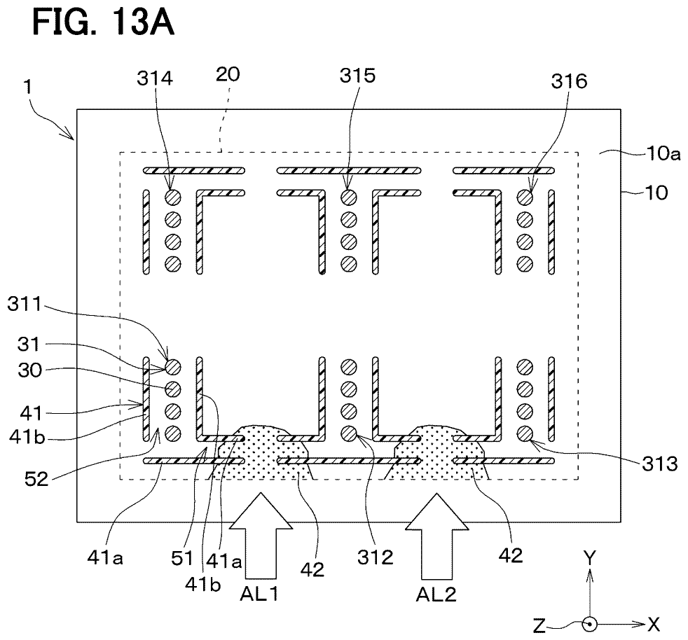

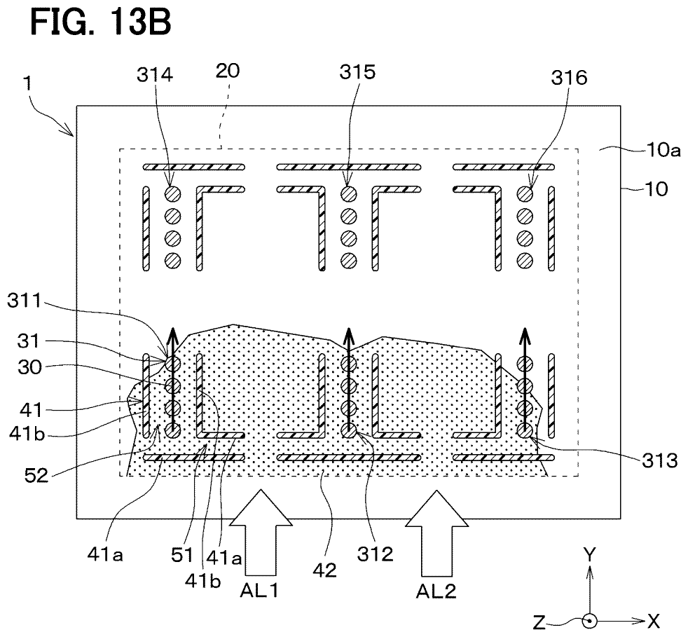

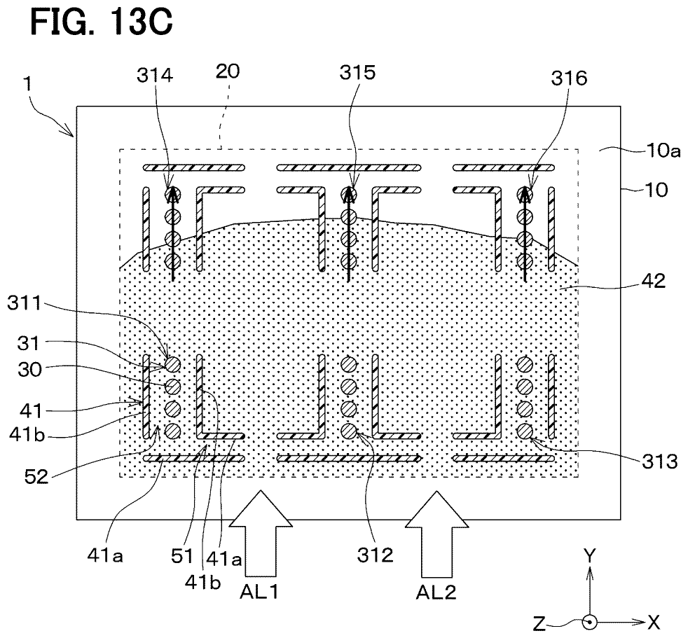

Therefore, in the present embodiment, when applying the insulating bonding material 42, as shown in FIG. 13A, the insulating bonding material 42 is applied from a first application position AL1 between the first bonding member group 311 and the second bonding member group 312, and from a second application position AL2 between the second bonding member group 312 and the third bonding member group 313. That is, the insulating bonding material 42 is applied from each position located between two bonding member groups 31 adjacent to each other. As a result, the insulating bonding material 42 applied from the first application position AL1 flows to the first bonding member group 311 and the second bonding member group 312, and the insulating bonding material 42 applied from the second application position AL2 flows to the second bonding member group 312 and the third bonding member group 313. At this time, since the application positions AL1, AL2 are located between the respective bonding member groups 31, it is possible to prevent the occurrence of merging due to the insulating bonding material 42 wrapping around as illustrated in FIG. 12. In addition, in the present embodiment, the first passage 51 arranged in the vicinity of the first bonding member group 311 is directed toward the second bonding member group 312, and the first passage 51 arranged in the vicinity of the second bonding member group 312 is directed toward the first bonding member group 311. Similarly, the first passage 51 arranged in the vicinity of the second bonding member group 312 is directed toward the third bonding member group 313, and the first passage 51 arranged in the vicinity of the third bonding member group 313 is directed toward the second bonding member group 312. Therefore, the insulating bonding material 42 applied from the first application position AL1 easily flows through the first passage 51 toward the first bonding member group 311 and the second bonding member group 312. Similarly, the insulating bonding material 42 applied from the second application position AL2 easily flows through the first passage 51 toward the second bonding member group 312 and the third bonding member group 313.

Then, as shown in FIG. 13B, when the insulating bonding material 42 reaches the second passages 52 in which the first to third bonding member groups 311 to 313 are arranged, the insulating bonding material 42 flows through the second passage 52 in the one direction. Thereafter, as shown in FIG. 13C, the insulating bonding material 42 maintains its flow direction and reaches the fourth to sixth bonding member groups 314 to 316. Therefore, in the fourth to sixth bonding member groups 314 to 316 as well, the occurrence of merging of the insulating bonding materials 42 can be suppressed, and the occurrence of voids V can be suppressed.

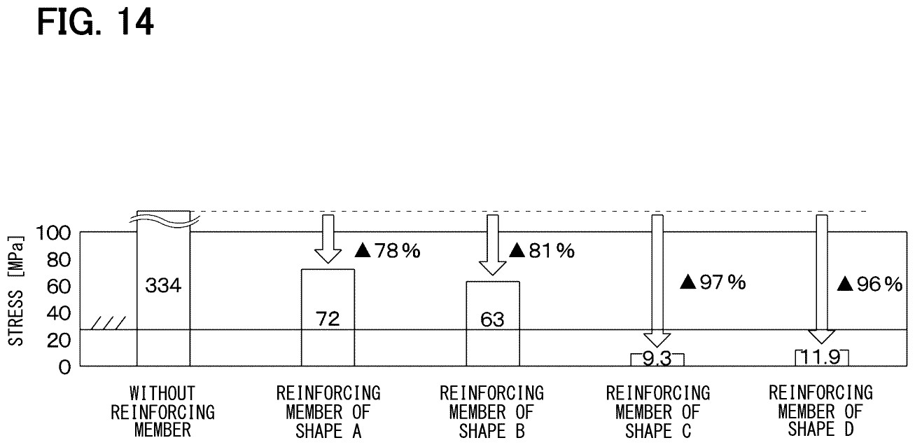

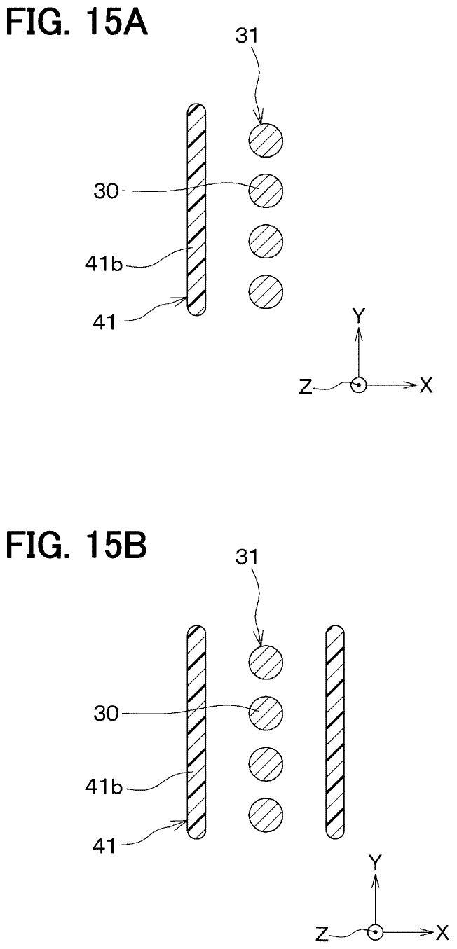

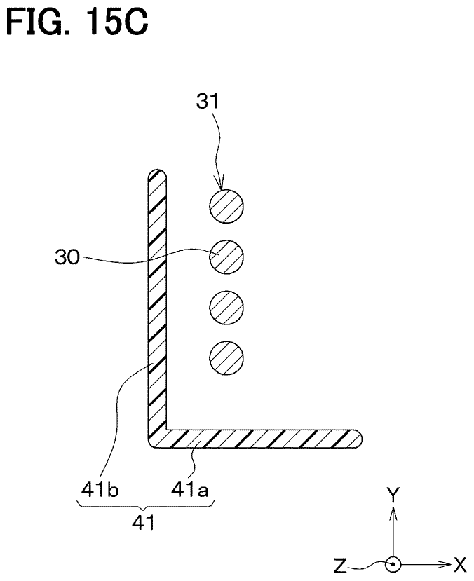

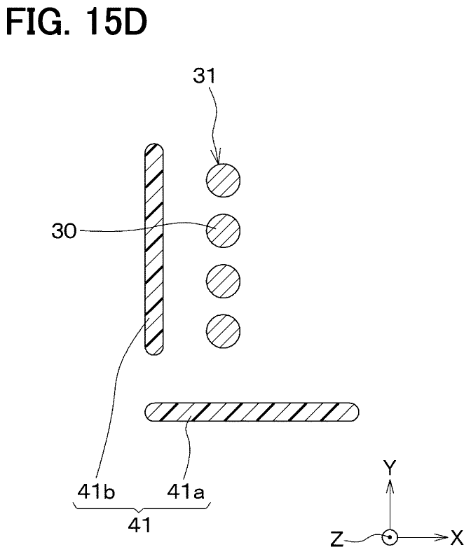

Even if each of the reinforcing members 41 is configured so that the first portion 41a and the second portion 41b are apart from each other as in the present embodiment, the stress generated in the conductive bonding members 30 can be sufficiently reduced when the temperature is lowered after the conductive bonding members 30 are fixed to the power module 10 and the circuit module 20. The present inventors have conducted extensive research into the relationship between the shape of the reinforcing member 41 and the stress generated in the conductive bonding member 30, and obtained the results shown in FIG. 14. Note that a reinforcing member of shape A in FIG. 14 is the result when the reinforcing member 41 is configured with only one second portion 41b extending along the bonding member group 31, as shown in FIG. 15A. A reinforcing member of shape B in FIG. 14 is the result when the reinforcing member 41 is configured with two second portions 41b that extend along the bonding member group 31 and are arranged to sandwich the bonding member group 31 therebetween, as shown in FIG. 15B. A reinforcing member of shape C in FIG. 14 is the result when the reinforcing member 41 is configured with the first portion 41a and the second portion 41b connected to form a substantially L-shape, as shown in FIG. 15C. A reinforcing member of shape D in FIG. 14 is the result when the reinforcing member 41 is configured with the first portion 41a and the second portion 41b arranged apart from each other, as shown in FIG. 15D.

As shown in FIG. 14, since the reinforcing member of shape C and the reinforcing member of shape D have the first portion 41a and the second portion 41b, it was confirmed that the stress generated in the conductive bonding member 30 can be sufficiently reduced compared to the reinforcing member of shape A and the reinforcing member of shape B. Furthermore, it was confirmed that even in the case of the reinforcing member of shape D, in which the first portion 41a and the second portion 41b are apart from each other, the stress generated in the conductive bonding member 30 can be sufficiently reduced compared to the reinforcing member of shape A and the reinforcing member of shape B. Note that, FIG. 14 shows a breaking strength of the conductive adhesive of about 30 MPa as a reference boundary.

According to the present embodiment described above, since each of the reinforcing members 41 has the first portion 41a and the second portion 41b, it is possible to obtain the same effects as those of the first embodiment.

In the present embodiment, each of the reinforcing members 41 has the gap at which the first portion 41a and the second portion 41b are apart from each other. Therefore, when the insulating bonding material 42 is applied, the occurrence of voids V can be suppressed.

In the present embodiment, each of the reinforcing members 41 has the two second portions 41b that sandwich the bonding member group 31 therebetween. Therefore, the flow direction of the insulating bonding material 42 relative to the bonding member group 31 can be easily made to be in the one direction, and the occurrence of voids V can be suppressed.

In the present embodiment, there are the plurality of bonding member groups 31. When the insulating bonding material 42 is applied, the insulating bonding material 42 is applied between each position located between two of the bonding member groups 31 adjacent to each other. This makes it possible to prevent the insulating bonding materials 42 from wrapping around and merging in the vicinity of the bonding member groups 31, and to prevent the occurrence of voids V inside the insulating bonding material 42.

### Third Embodiment

The following describes a third embodiment of the present disclosure. The present embodiment is different from the first embodiment in the configuration of the reinforcing members 41. The other configurations of the present embodiment are similar to those of the first embodiment, and therefore a description of the similar configurations will not be repeated.

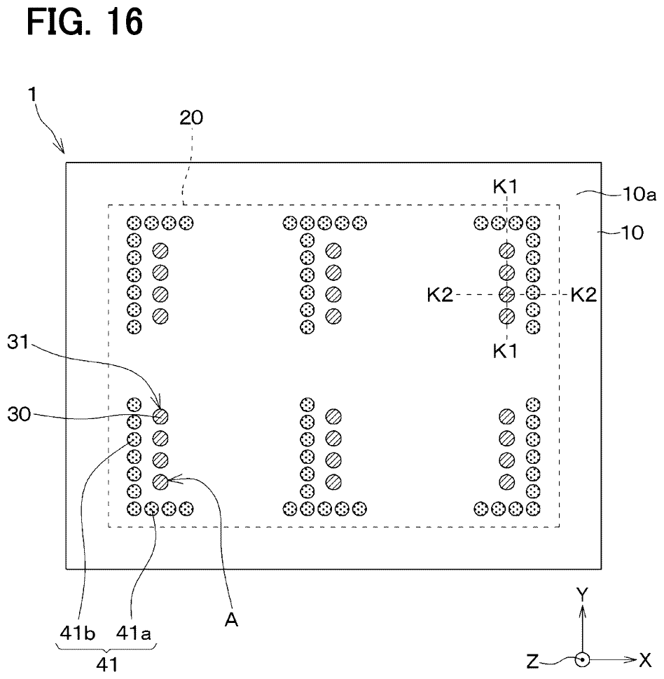

In the present embodiment, as shown in FIG. 16, each of the reinforcing members 41 is divided into a plurality of parts. Specifically, each of the reinforcing members 41 of the present embodiment is divided into a plurality of parts such that the first portion 41a and the second portion 41b have dotted shapes. FIG. 16 is a cross-sectional view corresponding to FIG. 3.

According to the present embodiment described above, since each of the reinforcing members 41 has the first portion 41a and the second portion 41b, it is possible to obtain the same effects as those of the first embodiment.

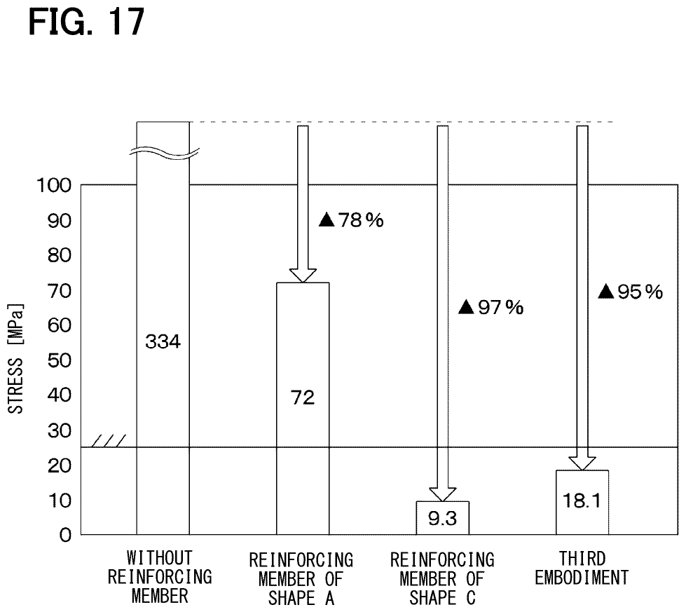

In the present embodiment, each of the reinforcing members 41 is divided into the plurality of parts. Therefore, when the insulating bonding material 42 is applied, the insulating bonding material 42 flows around each of the reinforcing members 41, making it difficult for air to be entrained, thereby suppressing the occurrence of voids V. Even if each of the reinforcing members 41 is divided into the plurality of parts, when the temperature is lowered after the conductive bonding members 30 are fixed to the power module 10 and the circuit module 20, the stress generated in the conductive bonding members 30 can be sufficiently reduced as shown in FIG. 17. The results of the reinforcing member of shape A and the reinforcing member of shape C shown in FIG. 17 are the same as the results of the reinforcing member of shape A and the reinforcing member of shape C in FIG. 14. The third embodiment in FIG. 17 is the result of the reinforcing member 41 in which the first portion 41a and the second portion 41b are formed in dotted shapes, as in the present embodiment. FIG. 17 shows a breaking strength of the conductive adhesive of about 30 MPa as a reference boundary.

### Other Embodiments

Although the present disclosure has been described in accordance with the embodiments, it is understood that the present disclosure is not limited to such embodiments or structures. The present disclosure encompasses various modifications and variations within the scope of equivalents. In addition, various combinations and configurations, as well as other combinations and configurations that include only one element, more, or less, fall within the scope and spirit of the present disclosure.

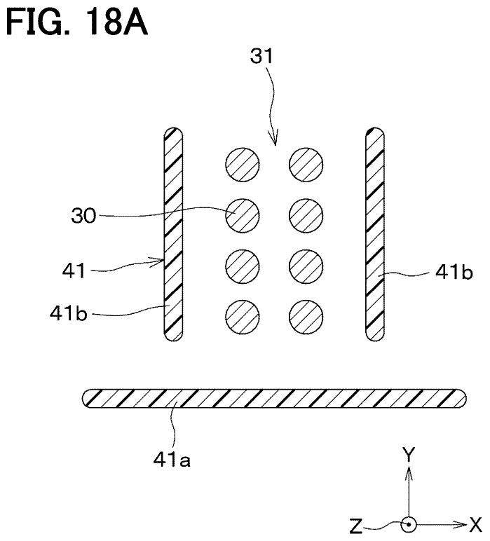

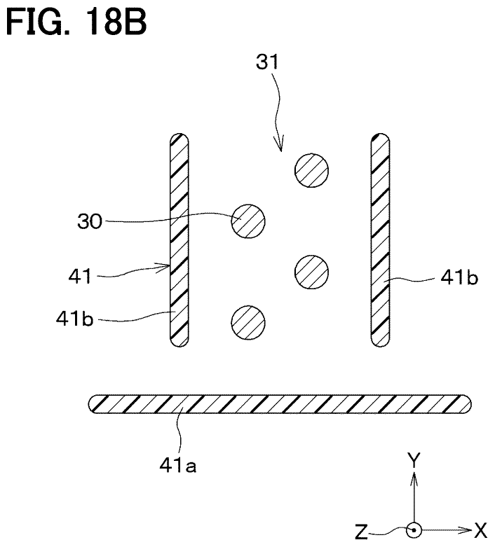

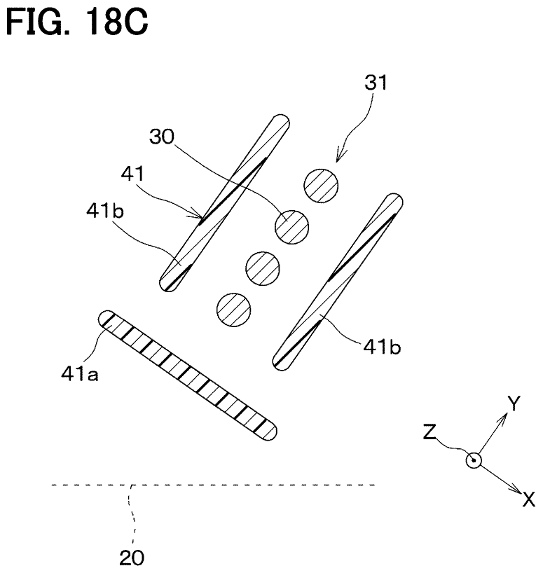

For example, in each of the above-described embodiments, the number and arrangement of the conductive bonding members 30 constituting each of the bonding member groups 31 can be appropriately changed. For example, as shown in FIG. 18A, four conductive bonding members 30 may be arranged along the Y-axis direction, and two sets of the four conductive bonding members 30 may be arranged along the X-axis direction. In another example, as shown in FIG. 18B, when two sets of conductive bonding members 30 are arranged along the X-axis direction, the conductive bonding members 30 may be arranged so as not to face each other in the X-axis direction. In another example, as shown in FIG. 18C, the Y-axis direction may be inclined with respect to the long side of the circuit module 20 rather than being perpendicular thereto. In other words, the X-axis direction does not have to be parallel to the long side of the circuit module 20, but may be inclined relative to it. The configuration of each of the reinforcing members 41 can also be changed as appropriate. For example, as shown in FIGS. 18A to 18C, each of the reinforcing members 41 may have two second portions 41b and one first portion 41a, with the first portion 41a positioned apart from the second portion 41b.

In each of the above-described embodiments, the power module 10 and the circuit module 20 may have a planar polygonal shape instead of a substantially rectangular shape.

In each of the above-described embodiments, the protrusion amount D of the first portion 41a and the second portion 41b may be less than 0 mm or may be greater than 10 mm. Similarly, in each of the above-described embodiments, the width W of each of the reinforcing members 41 may be less than 2 mm, or may be more than 6 mm.

In the second embodiment, each of the reinforcing members 41 may have one first portion 41a and one second portion 41b and the first portion 41a, and the second portion 41b may be spaced apart from each other, as shown in FIG. 15D. Even with this configuration, it is possible to suppress the occurrence of voids V in the portion between the first portion 41a and the second portion 41b.

In the third embodiment, only one of the first portion 41a and the second portion 41b may be divided into a plurality of parts. In the third embodiment, the division method can be changed as appropriate.

The third embodiment may be combined with the second embodiment, and each of the reinforcing members 41 may be divided into a plurality of parts.

What is claimed is:

1. An electronic module comprising:
a first circuit component having a surface on which a plurality of electrode pads are disposed;
a second circuit component laminated above the first circuit component, and having a surface facing the surface of the first circuit component and on which a plurality of electrode pads are disposed;
a plurality of conductive bonding members disposed between the plurality of electrode pads of the first circuit component and the plurality of electrode pads of the second circuit component, respectively, and electrically connecting the plurality of electrode pads of the first circuit component and the plurality of electrode pads of the second circuit component, respectively;
a plurality of reinforcing members disposed between the surface of the first circuit component and the surface of the second circuit component and bonded to the surface of the first circuit component and the surface of the second circuit component; and
an insulating bonding material disposed between the surface of the first circuit component and the surface of the second circuit component, bonded to the surface of the first circuit component and the surface of the second circuit component, and made of a material different from the plurality of conductive bonding members and the plurality of reinforcing members, wherein
the plurality of electrode pads of the first circuit component and the plurality of electrode pads of the second circuit component are arranged such that the plurality of conductive bonding members disposed between the plurality of electrode pads of the first circuit component and the plurality of electrode pads of the second circuit component form a plurality of bonding member groups, each of which includes two or more of the plurality of conductive bonding members arranged along one direction in a plane direction of the surface of the first circuit component, with the one direction being defined as an extension direction of each of the plurality of bonding member groups, and
each of the plurality of reinforcing members is disposed apart from an adjacent bonding member group among the plurality of bonding member groups, and each of the plurality of reinforcing members has a first portion that extends along a direction intersecting with the extension direction of the adjacent bonding member group, and a second portion that extends along the extension direction of the adjacent bonding member group.

2. The electronic module according to claim 1, wherein
in each of the plurality of reinforcing members, the first portion and the second portion are connected.

3. The electronic module according to claim 1, wherein
each of the plurality of reinforcing members has a gap at which the first portion and the second portion are apart from each other.

4. The electronic module according to claim 1, wherein
in each of the plurality of reinforcing members, at least one of the first portion and the second portion is divided into a plurality of parts.

5. The electronic module according to claim 1, wherein
each of the plurality of reinforcing members has, as the second portion, two second portions arranged to sandwich the adjacent bonding member group.

6. The electronic module according to claim 1, wherein
in each of the plurality of reinforcing members, an end of the first portion located opposite the second portion protrudes from the adjacent bonding member group to an opposite side from the second portion, an end of the second portion located opposite the first portion protrudes from the adjacent bonding member group to an opposite side from the first portion, and a protrusion amount of the first portion from the adjacent bonding member group and a protrusion amount of the second portion from the adjacent bonding member group are greater than 0 mm and less than or equal to 10 mm.

7. The electronic module according to claim 1, wherein
each of the plurality of reinforcing members has a width of 2 mm or more and 6 mm or less.

8. The electronic module according to claim 1, wherein
the plurality of reinforcing members and the insulating bonding material have higher coefficients of linear expansion than the plurality of conductive bonding members.

9. The electronic module according to claim 1, wherein
the plurality of conductive bonding members are made of a conductive adhesive.

10. The electronic module according to claim 1, wherein
the plurality of reinforcing members are made of a same material as the plurality of conductive bonding members.

11. A manufacturing method of an electronic module that includes:
a first circuit component having a surface on which a plurality of electrode pads are disposed;
a second circuit component laminated above the first circuit component, and having a surface facing the surface of the first circuit component and on which a plurality of electrode pads are disposed;
a plurality of conductive bonding members disposed between the plurality of electrode pads of the first circuit component and the plurality of electrode pads of the second circuit component, respectively, and electrically connecting the plurality of electrode pads of the first circuit component and the plurality of electrode pads of the second circuit component, respectively;
a plurality of reinforcing members disposed between the surface of the first circuit component and the surface of the second circuit component and bonded to the surface of the first circuit component and the surface of the second circuit component; and
an insulating bonding material disposed between the surface of the first circuit component and the surface of the second circuit component, bonded to the surface of the first circuit component and the surface of the second circuit component, and made of a material different from the plurality of conductive bonding members and the plurality of reinforcing members, wherein
the plurality of electrode pads of the first circuit component and the plurality of electrode pads of the second circuit component are arranged such that the plurality of conductive bonding members disposed between the plurality of electrode pads of the first circuit component and the plurality of electrode pads of the second circuit component form a plurality of bonding member groups, each of which includes two or more of the plurality of conductive bonding members arranged along a first direction in a plane direction of the surface of the first circuit component, with the first direction being defined as an extension direction of each of the plurality of bonding member groups, and
each of the plurality of reinforcing members is disposed apart from an adjacent bonding member group among the plurality of bonding member groups, and each of the plurality of reinforcing members has a first portion that extends along a direction intersecting with the extension direction of the adjacent bonding member group, and a second portion that extends along the extension direction of the adjacent bonding member group,
the manufacturing method comprising:
preparing the first circuit component and the second circuit component;
disposing the plurality of conductive bonding members and the plurality of reinforcing members between the first circuit component and the second circuit component; and
disposing the insulating bonding material between the first circuit component and the second circuit component by flowing the insulating bonding material, wherein
the preparing of the first circuit component and the second circuit component includes arranging the plurality of electrode pads of the first circuit component and the plurality of electrode pads of the second circuit component such that three or more of the plurality of bonding member groups are to be arranged in a second direction of the plane direction of the first circuit component, and
the disposing of the insulating bonding material includes applying the insulating bonding material from each position located between two of the plurality of bonding member groups that are adjacent to each other in the second direction.
